(19) United States
(12) Patent Application Publication
(10) Pub. No.: US 2009/0317644 A1
(43) Pub. Date: Dec. 24, 2009

(54) Methods for Manufacturing a Structure on a Substrate, Method for Manufacturing a Semiconductor Device and an Intermediate Product

(76) Inventors: Marcel Heller, Stolpen (DE); Lars Voelkel, Dresden (DE)

Correspondence Address: SLATER & MATSIL, L.L.P., 17950 PRESTON ROAD, SUITE 1000, DALLAS, TX, 75252, US

(21) Appl. No.: 12/142,140

(22) Filed: Jun. 19, 2008

(51) Int. Cl. B32B 15/08; C23F 1/02; H01L 21/311

(52) U.S. Cl. 428/461; 216/67; 438/703; 257/E21.249

(57) ABSTRACT

Methods for manufacturing a semiconductor device or a structure on a substrate are provided, e.g., with a polymer structure including a first polymer including at least one of the group of silicon, titanium and zirconium. The polymer structure is covered on sidewalls at least partially with a second polymer. The first polymer has a different etch selectivity from the second polymer. The first polymer and the second polymer are thermally treated to initiate a growth of crosslinked second polymer on the structures of the first polymer resulting in a spacer out of the second polymer around the first polymer. In a further process, one of the group of the first polymer and the second polymer is selectively removed from the other polymer by an etching process. An intermediate product is also described.

### BACKGROUND

In the manufacturing of semiconductor devices, such as, e.g., memory chips, DRAM chips, microprocessors, optoelectronic, electromechanical devices, mask devices or bio-chips, it is often necessary to structure a substrate. A substrate can be, e.g., a silicon wafer, a germanium wafer, a glass substrate or a III-V material wafer. Furthermore, the substrate can comprise already some structures which have been manufactured in previous processes.

Known processes used in the manufacturing of semiconductors can be, e.g., the exposure to radiation in a lithography process, the deposition of material layers on the substrate, the etching of the substrate or the doping of the substrate with dopants. The person skilled in the art will recognize that other processes are used in the manufacturing of semiconductor devices.

### SUMMARY OF THE INVENTION

One embodiment provides a method for manufacturing a structure on a substrate with a polymer structure including a first polymer including at least one of the group of silicon, titanium and zirconium. The polymer structure is covered on sidewalls at least partially with a second polymer. The first polymer has a different etch selectivity from the second polymer. The first polymer and the second polymer are thermally treated to initiate a growth of crosslinked second polymer on the structures of the first polymer resulting in a spacer out of the second polymer around the first polymer. In a further process, one of the group of the first polymer and the second polymer is selectively removed from the other polymer by an etching process.

After the thermal treatment, the remaining non-crosslinked second polymer can be optionally removed by a solvent. In a further process, one of the polymers is selectively removed from the other polymer by an etching process.

Another embodiment provides a method for manufacturing a structure on a substrate with a polymer structure including a first polymer including at least one of the group of metal or semiconductor material. The polymer structure is covered on sidewalls at least partially with a second polymer as spacer structure. The first polymer has a different etch selectivity from the second polymer. The first polymer and the second polymer are thermally treated to initiate a crosslinking between the first polymer and the second polymer for a defined growth of the second polymer on the first polymer. In a further process, one of the polymers is selectively removed from the other polymer by an etching process. In a further process, the first polymer or the second polymer is selectively removed from the other polymer by an etching process, wherein a structure including at least one of the group of the first polymer and the second polymer is forming a hard mask which is used to structure the substrate.

An intermediate semiconductor product is also described. A polymer structure is disposed on a substrate. The polymer structure comprises a first polymer, which comprises at least one of the group of silicon, titanium and zirconium. The polymer structure is covered on sidewalls at least partially with a second polymer. The first polymer has a different etch selectivity from the second polymer. The first polymer and the second polymer are thermally treated to initiate a crosslinking between the first polymer and the second polymer.

### BRIEF DESCRIPTION OF THE DRAWINGS

FIG. 1 shows a schematic cross-section of a first embodiment with a polymer structure,

FIG. 2 shows a schematic cross-section of the embodiment of FIG. 1 after a second polymer has been deposited, cross-linked and treated with solvent;

FIG. 3 shows a schematic cross-section of the embodiment of FIG. 2 after a further material has been applied;

FIG. 4 shows a schematic cross-section of the embodiment of FIG. 3 after the upper part has been etched back;

FIG. 5 shows a schematic cross-section of the embodiment of FIG. 4 after the removal of spacers;

FIG. 6 shows a schematic cross-section of the embodiment of FIG. 5 after a structuring of the substrate;

FIG. 7 shows a schematic cross-section of a second embodiment;

FIG. 8 shows a schematic cross-section of the second embodiment according to FIG. 7 in which the first polymer has been removed by etching; and

FIG. 9 shows a flow chart of an embodiment of the method.

### DETAILED DESCRIPTION OF ILLUSTRATIVE EMBODIMENTS

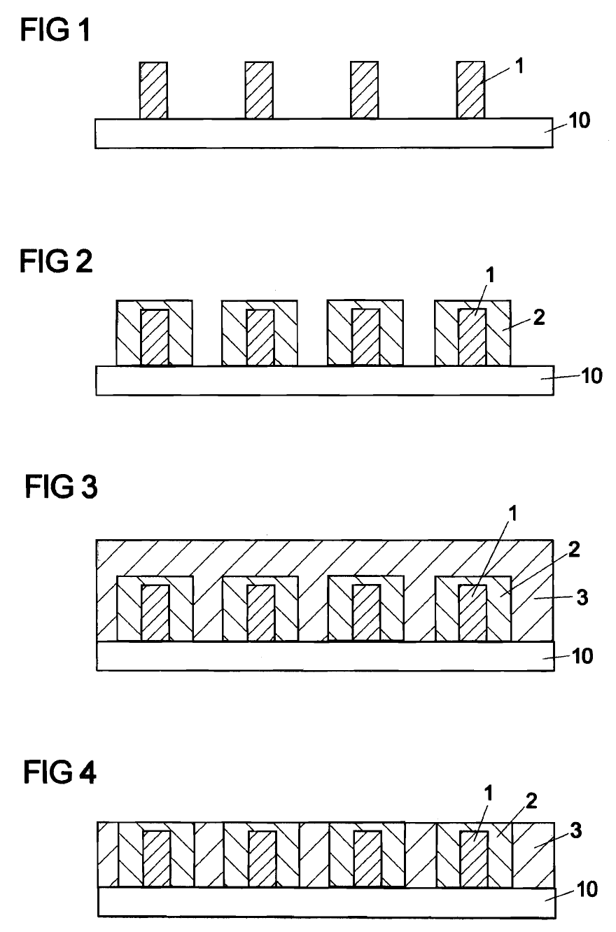

In FIG. 1 a schematic cross-section through a substrate 10 with a polymer structure 1 is shown. For the sake of simplicity, the substrate 10 is shown without a structure that could have been manufactured in a previous process. Such previous structuring could, e.g., involve etching, deposition and/or lithographic processes.

The polymer structure 1 comprises a number of line elements. In alternative embodiments, other shapes such as holes or annular structures can be used additionally or alternatively. For example, the polymer structure could comprise quadratic or round shapes.

The polymer structure 1 comprises polymer material, such as, e.g., a bilayer resist. The polymer structure 1 in FIG. 1 can be manufactured with lithographic processes generally known in the art. The polymer structure 1 comprises silicon, titanium and/or zirconium. Silicon, titanium or zirconium are covalently bound on the resist polymer or are embedded in the matrix of the resist. Resists (or photoresists) are used in a variety of ways in lithographic techniques in the manufacturing of semiconductors. In general, a photoreaction is initiated in the resist by exposure to electromagnetic radiation (e.g,. visible light, UV-light, DUV-light or EUV light) which causes a change in the chemical structure of the resist. This results in a change in the solubility of the exposed regions of the resist. In the case of positive, chemically amplified resists, for example, the exposure liberates an acid which causes a catalytic conversion or cleavage of the resist in a postbake step. The strong acid eliminates acid-labile groups of the polymer. Polar groups are thereby liberated. Groups cleavable by strong acids are, for example, tert-butyl carboxylates, which are present as free carboxyl groups after acid cleavage. The change from a strongly nonpolar to a polar group results in a change in the solubility of the exposed and chemically modified resist in a suitable developer medium, such as, for example, an aqueous basic developer.

In the case of a negative resist, the exposed part of the resist remains on the substrate. In the case of the chemically amplified negative resists, for example, the exposure liberates a strong acid that causes acid-catalyzed crosslinking of the resist polymers in the postbake step. Due to the crosslinking, the exposed part becomes insoluble whereas the unexposed part can be removed in suitable (generally aqueous) developers.

Alternatively, many positive-working chemically amplified resists can be used as negative resists if, after elimination of the protective groups, the chemically modified resist is developed not with an aqueous alkaline developer but with a nonpolar solvent. In this case, the nonpolar, chemically substantially unmodified resist parts are detached from the substrate.

In FIG. 2 the result of further processing of the structure in FIG. 1 is shown. The polymer structure 1 is covered on its sidewalls at least partially with a second polymer 2. In one embodiment the sidewall covering of the polymer structure 1 provides a spacer structure. The second polymer 2 comprises at least commercially available CD shrink material (e.g., RELACS (AZEM) or SAPHIRE (TOK)).

The first polymer and the second polymer 2 differ in etch selectivity, so that they react differently to an etch process. Furthermore, the first polymer and the second polymer 2 are thermally treated (e.g., through a bake process) to initiate a crosslinking between the first polymer and the second polymer. The thermal treatment can be performed, e.g., in the temperature 80 to 250° C., in particular 100 to 200° C.

Non-crosslinked parts of the second polymer can be removed, e.g., by an aqueous solvent, a non-aqueous solvent or a developer.

The result is an intermediate product in the manufacturing of semiconductors which can be further processed in different ways. In the following some embodiments are depicted.

In one embodiment, the polymer structure 1 and the second polymer 2 are covered at least partially with a further material 3 as shown in FIG. 3. The further material can comprise a resist, a bilayer resist and/or silicon and/or titanium containing BARC (Bottom Antireflective Coating).

In FIG. 4 a further processing of the substrate according to FIG. 3 is shown. The further material 3 is etched back, e.g., by a plasma etch process. One possibility is the etching with a fluorinated plasma. Chlorine plasma or fluoro-hydrocarbon (CₓH_{y}F_{z}) plasma are also possible. Now a planar surface can be generated as can be seen in FIG. 4.

In FIG. 5 one possible alternative for a further processing is shown. In this embodiment the second polymer 2, i.e., the spacer at the sidewall of the polymer structure 1 is selectively removed by an etch process. The second polymer 2 can be removed, e.g., by an oxygen and/or hydrogen containing plasma, which can selectively remove the second polymer 2.

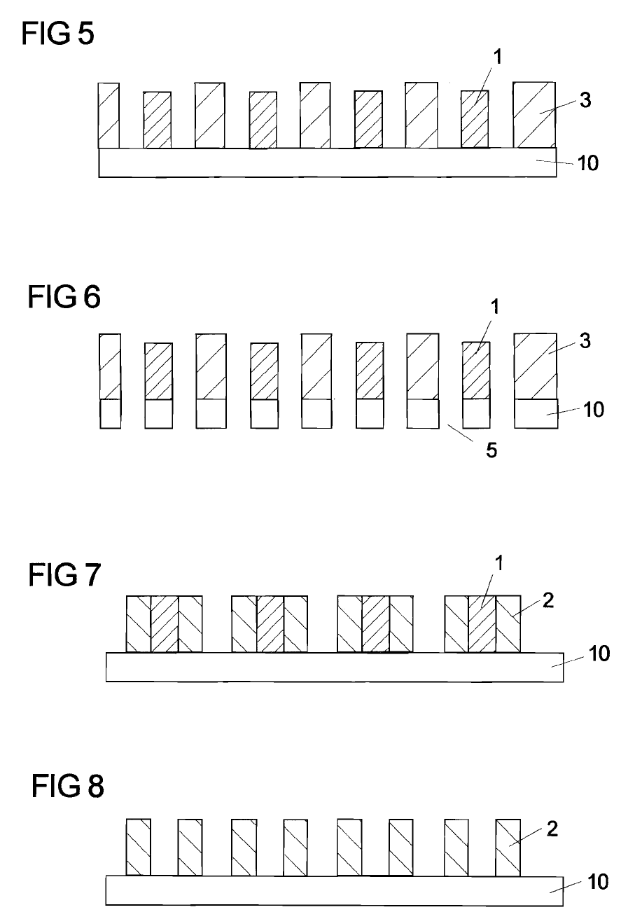

In FIG. 6 it is depicted that the pattern of the first structure 1 and the further material 3 can be used has hard mask to structure 5 the substrate 10 underneath. In case the substrate 10 comprises an organic BARC material, the structuring can be performed with a plasma comprising O₂ or H₂.

In FIG. 7 an alternative second embodiment is depicted, which uses the situation as shown in FIG. 2 as starting point. Here the cap of the second polymer 2 is removed by etching. Then the first polymer 1 is selectively removed by an anisotropic etch process (see FIG. 8). Now this pattern can be used as hard mask for the further processing of the substrate. The etching of the cap of the second polymer 2 and the anisotropic etch process are performed with etch media having different selectivities.

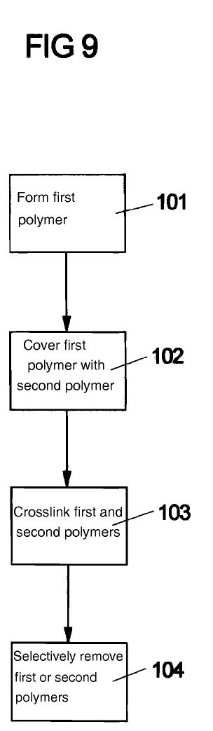

In FIG. 9 one embodiment of the method is described in the form of a flow chart.

In one process step 101 a polymer structure 1 comprising a first polymer comprising silicon, titanium or zirconium, is deposited on a substrate 10.

In a subsequent process step 102 the polymer structure is covered on its sidewalls at least partially with a second polymer. The first polymer having a different etch selectivity from the second polymer.

In a further subsequent process step 103 the first polymer and the second polymer are thermally treated to initiate a crosslinking between the first polymer and the second polymer.

In a further process step 104 one of the group of the first polymer and the second polymer is selectively removed from the other polymer by an etching process.

Those process steps 101, 102, 103, 104 do not have to be necessarily immediately in sequence. Other process steps can take place in-between.

What is claimed is:

1. A method for manufacturing a structure on a substrate, the method comprising:
forming a polymer structure over a substrate, the polymer structure comprising a first polymer material comprising silicon, titanium and/or zirconium;
at least partially covering sidewalls the polymer structure with a second polymer material, the first polymer material having a different etch selectivity that the second polymer material;
thermally treating the first polymer material and the second polymer material to initiate a growth of crosslinked second polymer material on the polymer structure, the second polymer material forming a spacer adjacent the polymer structure; and
selectively removing either the first polymer material or the second polymer material using an etching process.

2. The method according to claim 1, further comprising depositing a further material that at least partially fills gaps between the sidewalls covered by the second polymer material.

3. The method according to claim 2, wherein the further material comprises at least one silicon, titanium and/or zirconium.

4. The method according to claim 2, further comprising using a structure comprising at least one of the further material, the first polymer material and/or the second polymer material as a mask structure for further processing of the substrate.

5. The method according to claim 4, wherein the mask structure comprises a hard mask.

6. The method according to claim 1, wherein selectively removing comprises removing the first polymer material by anisotropic etching.

7. The method according to claim 1, wherein the first polymer material comprises resist, bilayer resist and/or silicon BARC.

8. The method according claim 1, wherein the first polymer material comprises functional groups that enable covalent bonding or cross-linking with the second polymer material.

9. The method according to claim 8, wherein the first polymer material comprises free —OH groups for crosslinking or covalent bonding with the second polymer material.

10. The method according to claim 1, wherein forming the polymer structure comprises performing a lithography process.

11. The method according to claim 1, wherein the polymer structure comprises a line structure.

12. The method according to claim 1, wherein the second polymer material comprises a CD shrink material.

13. The method according to claim 1, wherein the thermally treating takes place for about 50 to 90 seconds.

14. The method according to claim 1, wherein the thermally treating takes place in the temperature range of about 100-200° C.

15. The method according to claim 2, wherein the further material comprises resist, bilayer resist and/or silicon/titanium BARC.

16. The method according to claim 1, wherein selectively removing comprises selectively etching the second polymer material using plasma comprising an oxygen or hydrogen chemistry.

17. The method according to claim 2, further comprising etching the further material using a plasma etch process with fluorinated plasma, chlorine plasma and/or fluor-hydrocarbon plasma.

18. A method of manufacturing a semiconductor device, the method comprising:
forming a polymer structure over a substrate, the polymer structure comprising a first polymer comprising silicon, titanium and/or zirconium;
at least partially covering sidewalls of the polymer structure with a second polymer, the first polymer having a different etch selectivity from the second polymer;
thermally treating the first polymer and the second polymer to initiate a growth of crosslinked second polymer on the polymer structure of the first polymer resulting in a spacer out of the second polymer around the first polymer; and
selectively removing one of the first polymer or the second polymer from the other polymer using an etching process.

19. The method according to claim 18, wherein the semiconductor device comprises a memory chip, DRAM-chip, flash memory chip, microprocessor, optoelectronic device, bio-chip and microelectromechanical device.

20. A method for manufacturing a structure on a substrate, the method comprising:
forming a polymer structure comprising a first polymer comprising at least one of a metal or semiconductor material, the polymer structure being covered on sidewalls at least partially with a second polymer as a spacer structure, the first polymer having a different etch selectivity from the second polymer;
thermally treating the first polymer and the second polymer to initiate a crosslinking between the first polymer and the second polymer;
selectively removing one of the first polymer or the second polymer from the other polymer by an etching process; and
structuring the substrate using a structure comprising the first polymer and/or the second polymer as a hard mask.

21. An intermediate semiconductor product with a polymer structure on a substrate, the polymer structure comprising a first polymer, which comprises a metal and/or a semiconductor material, the polymer structure being covered on sidewalls at least partially with a second polymer, the first polymer having a different etch selectivity from the second polymer, the first polymer and the second polymer being thermally treated to initiate a crosslinking between the first polymer and the second polymer.
